(19) United States
(12) Patent Application Publication
(10) Pub. No.: US 2022/0399518 A1
(43) Pub. Date: Dec. 15, 2022

(54) BLUE ORGANIC LIGHT-EMITTING DIODE AND DISPLAY DEVICE

(71) Applicant: BOE TECHNOLOGY GROUP CO., LTD., Beijing (CN)

(72) Inventors: Xueqin CHEN, Beijing (CN); Congcong JIA, Beijing (CN); Yuqian SUN, Beijing (CN)

(21) Appl. No.: 17/776,649

(22) PCT Filed: Jun. 8, 2021
(86) PCT No.: PCT/CN2021/098859

§ 371 Date: May 13, 2022

(30) Foreign Application Priority Data
Jul. 28, 2020 (CN) 202010735466.1

(51) Int. Cl. H01L 51/50; H01L 27/32

(52) U.S. Cl. CPC H01L 51/5012; H01L 27/3211; H01L 51/5004; H01L 51/56

(57) ABSTRACT

The present disclosure provides a blue organic light-emitting diode. The blue organic light-emitting diode comprises a hole transport layer, a co-evaporation layer, a blue light-emitting auxiliary layer, a blue light-emitting layer, and an electron transport layer which are sequentially stacked. A material of the co-evaporation layer includes a mixture of a material of the hole transport layer and a material of the blue light-emitting auxiliary layer. The present disclosure also provides a display device. The display device has a good display effect under a low gray scale.

### CROSS REFERENCE TO RELATED APPLICATION

The present application claims priority to the Chinese patent application No. 202010735466.1 entitled “Blue Organic Light-Emitting Diode and Display Device” filed on Jul. 28, 2020.

### TECHNICAL FIELD

The present disclosure relates to the field of display technology, in particular, to a blue organic light-emitting diode and a display device including the same.

### BACKGROUND

Organic light-emitting diode display devices have been widely applied due to their advantages of wide color gamut, solid-state luminescence, flexibility, and the like.

In general, a pixel unit of an organic light-emitting diode display device includes a red organic light-emitting diode, a blue organic light-emitting diode and a green organic light-emitting diode. Existing organic light-emitting diode display devices generally have a phenomenon of low gray scale color shift, influencing display effect.

### SUMMARY

An object of the present disclosure is to provide a blue organic light-emitting diode and a display device including the blue organic light-emitting diode.

As a first aspect of the present disclosure, there is provided a blue organic light-emitting diode, including: a hole transport layer, a co-evaporation layer, a blue light-emitting auxiliary layer, a blue light-emitting layer and an electron transport layer which are sequentially stacked, wherein a material of the co-evaporation layer includes a mixture of a material of the hole transport layer and a material of the blue light-emitting auxiliary layer.

In some embodiments, a weight percentage of the material of the blue light-emitting auxiliary layer in the co-evaporation layer is 50 wt % to 99.9 wt %.

In some embodiments, a difference between a HOMO energy level of the blue light-emitting auxiliary layer and a HOMO energy level of the blue light-emitting layer is not more than 0.3 eV.

In some embodiments, the HOMO energy level of the blue light-emitting auxiliary layer is between −6 eV and −5.5 eV.

In some embodiments, the HOMO energy level of the blue light-emitting auxiliary layer is between −6 eV and −5.6 eV.

In some embodiments, a thickness of the co-evaporation layer is between 1 nm and 50 nm.

In some embodiments, the thickness of the co-evaporation layer is between 3 nm and 20 nm.

In some embodiments, the blue organic light-emitting diode further includes an anode on a side of the hole transport layer away from the co-evaporation layer, a hole block layer disposed between the blue light-emitting layer and the electron transport layer, and a cathode on a side of the electron transport layer away from the hole block layer.

In some embodiments, the blue organic light-emitting diode further includes a hole injection layer between the anode and the hole transport layer.

In some embodiments, the blue organic light-emitting diode further includes an electron injection layer between the cathode and the electron transport layer.

As a second aspect of the present disclosure, there is provided a display device including a plurality of pixel units, each pixel unit including a plurality of organic light-emitting diodes capable of emitting light of different colors, the plurality of organic light-emitting diodes including a blue organic light-emitting diode that emits blue light, wherein the blue organic light-emitting diode is the above blue organic light-emitting diode according to the present disclosure.

In some embodiments, the display device is a flexible display device.

In the blue organic light-emitting diode according to the present disclosure, since the material of the co-evaporation layer includes the material of the hole transport layer and the material of the blue light-emitting auxiliary layer, an interface barrier between the co-evaporation layer and the hole transport layer is small, and an interface barrier between the co-evaporation layer and the blue light-emitting auxiliary layer is also small, thus holes can smoothly pass through the co-evaporation layer.

Holes has a greater transport speed than electrons. In a case where the blue organic light-emitting diode emits light under a low current, the holes can be smoothly injected into the blue light-emitting layer after being sequentially buffered by the co-evaporation layer and the blue light-emitting auxiliary layer between the hole transport layer and the blue light-emitting layer in an injection process, without being accumulated at an interface between the blue light-emitting auxiliary layer and the blue light-emitting layer, such that the blue organic light-emitting diode can emit light normally, which in turn avoids a redness phenomenon under low gray scale display of the display device including the blue organic light-emitting diode, and improves the display effect of the display device.

### BRIEF DESCRIPTION OF DRAWINGS

The accompanying drawings, which are used for providing further understanding of the present disclosure and form a part of the specification, are used for explaining the present disclosure together with the following specific implementations, rather than limiting the present disclosure. In the accompanying drawings:

FIG. 1 is a schematic structural diagram of a blue organic light-emitting diode according to an embodiment of the present disclosure; and

FIG. 2 is a graph illustrating a comparison result of an IVL test performed on a blue organic light-emitting diode according to an embodiment and a blue organic light-emitting diode according to a comparative example.

### DETAIL DESCRIPTION OF EMBODIMENTS

The specific implementations of the present disclosure will be described in detail below in conjunction with the accompanying drawings. It should be understood that the specific implementations as described herein are only for illustrating and explaining, instead of limiting, the present disclosure.

An organic light-emitting diode includes an anode, a hole transport layer (HTL), a co-evaporation layer, a light-emitting auxiliary layer (also referred to as a prime layer), a light-emitting layer (also referred to as an emission layer; EML), an electron transport layer (ETL), and a cathode which are sequentially stacked. In the related art, a material of a blue light-emitting layer of a blue organic light-emitting diode is a single-component fluorescent material, thus the blue light-emitting layer has a relatively deep HOMO energy level, resulting in mismatch between HOMO energy levels of the hole transport layer and the blue light-emitting layer and a relatively large difference between the HOMO energy level of the blue light-emitting auxiliary layer and the HOMO energy level of the blue light-emitting layer. In the case of a low current injection, the holes cannot cross the difference between the HOMO energy levels of the blue light-emitting auxiliary layer and the blue light-emitting layer, resulting in a large number of holes accumulated at the interface between the blue light-emitting auxiliary layer and the blue light-emitting layer. At the same time, a large number of electrons enter the blue light-emitting layer, resulting in a large number of excitons at the interface between the blue light-emitting auxiliary layer and the blue light-emitting layer, which causes quenching, results in poor performance and low blue light brightness of the blue organic light-emitting diode device under a low current density, and further results in a phenomenon of low gray scale redness (one type of color shift) of the organic light-emitting diode display device.

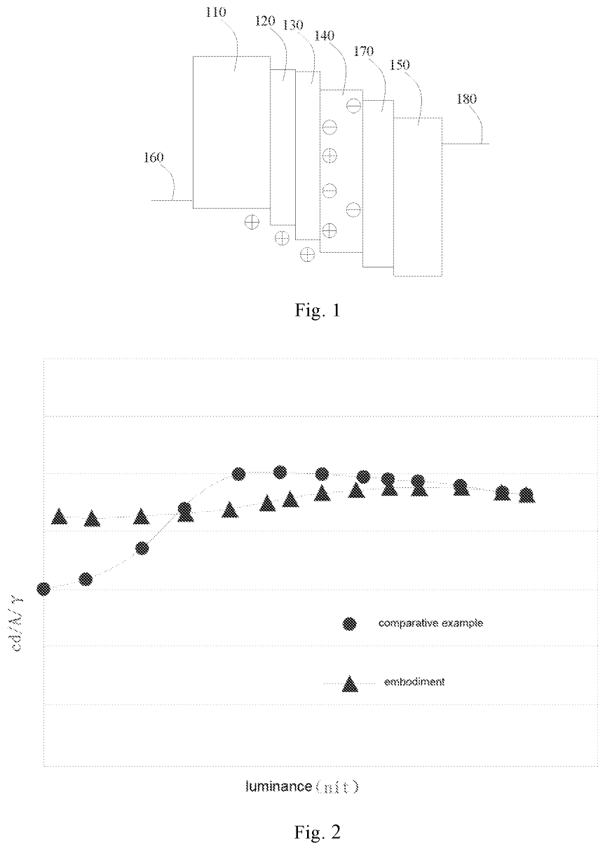

In view of the above, as a first aspect of the present disclosure, there is provided a blue organic light-emitting diode. As shown in FIG. 1, the blue organic light-emitting diode includes a hole transport layer 110, a co-evaporation layer 120, a blue light-emitting auxiliary layer 130, a blue light-emitting layer 140, and an electron transport layer 150 which are sequentially stacked. A material of the co-evaporation layer 120 includes a mixture of a material of the hole transport layer and a material of the blue light-emitting auxiliary layer.

Since the material of the co-evaporation layer 120 includes the material of the hole transport layer 110 and the material of the blue light-emitting auxiliary layer 130, the interface barrier between the co-evaporation layer 120 and the hole transport layer 110 is small, the interface barrier between the co-evaporation layer 120 and the blue light-emitting auxiliary layer 130 is also small, and thus holes can smoothly pass through the co-evaporation layer 120.

The transport speed of holes is greater than that of electrons. In a case where the blue organic light-emitting diode emits light under a low current, holes can be smoothly injected into the blue light-emitting layer 140 after being sequentially buffered by the co-evaporation layer 120 and the blue light-emitting auxiliary layer 130 between the hole transport layer 110 and the blue light-emitting layer 140 in an injection process, without being accumulated at an interface between the blue light-emitting auxiliary layer 130 and the blue light-emitting layer 140, so that the blue organic light-emitting diode can emit light normally, which in turn avoids a redness phenomenon under low gray scale display of the display device including the blue organic light-emitting diode, and improves the display effect of the display device.

In the present disclosure, the blue light-emitting auxiliary layer 130 also serves as an electron block layer (EBL).

In the present disclosure, compositions of materials of the co-evaporation layer 120 are not particularly limited as long as the material of the blue light-emitting auxiliary layer 130 and the material of the hole transport layer are included.

As an optional implementation, a weight percentage of the material of the blue light-emitting auxiliary layer in the co-evaporation layer 120 is 50 wt % to 99.9 wt %.

After the material of the hole transport layer and the material of the blue light-emitting auxiliary layer are mixed, since the HOMO energy level of the material of the hole transport layer is shallow, holes will first enter the material of the hole transport layer after the blue organic light-emitting diode is powered on. In the present disclosure, the material of the co-evaporation layer 120 is set such that a proportion of the material of the blue light-emitting auxiliary layer is higher than that of the material of the hole transport layer, which helps holes enter into not only the material of the blue light-emitting auxiliary layer but also the material of the hole transport layer in the co-evaporation layer 120, thereby facilitating normal emission of the blue organic light-emitting diode.

In the present disclosure, the specific material of the blue light-emitting auxiliary layer 130 is not particularly limited, for example, a dibenzofuran-triphenylamine derivative may be selected as the material of the blue light-emitting auxiliary layer 130.

In the present disclosure, the specific material of the hole transport layer 110 is not particularly limited, for example, any one of TPD, NPB, PVK, Spiro-TPD and Spiro-NPB may be selected as the material of the hole transport layer 110.

As an optional implementation, the difference between the HOMO energy level of the blue light-emitting auxiliary layer 130 (HOMO_Bprime) and the HOMO energy level of the blue light-emitting layer 140 (HOMO_BEML) is not more than 0.3 eV (i.e., HOMO_Bprime-HOMO_BEML≤0.3 eV) to ensure that holes can be smoothly injected into the light-emitting layer. Specifically, in the case of a low current density, a driving voltage is determined by the energy level difference (gap) between the blue light-emitting auxiliary layer and the blue light-emitting layer, and an energy level difference of less than 0.3 eV indicates that the two layers have a small energy level difference, and holes can easily transition without increasing a voltage.

In the related art, the HOMO energy level of the blue light-emitting auxiliary layer is between −5.4 eV and −5.5 eV. In the present disclosure, the blue light-emitting auxiliary layer may be made from a material with a relatively deep HOMO energy level. As an optional implementation, the HOMO energy level of the blue light-emitting auxiliary layer 130 is between −6 eV and −5.5 eV. Accordingly, the blue light-emitting auxiliary layer 130 may be made from a material selected from carbazole triphenylamine derivatives, furan triphenylamine derivatives, fluorene triphenylamine derivatives, and the like.

Accordingly, the HOMO energy level of the blue light-emitting layer 140 may be between −6.3 eV and −5.8 eV, and the blue light-emitting layer 140 may be made from a material selected from 9,10-dinaphthylanthracene-like materials, 9,10-diphenylanthracene-like materials, dibenzofuran-anthracene derivatives, and the like.

In order to reduce an overall thickness of the blue organic light-emitting diode, In some embodiments, the co-evaporation layer 120 may have a thickness between 1 nm and 50 nm. Accordingly, the hole transport layer 110 may have a thickness between 90 nm and 120 nm, and the blue light-emitting auxiliary layer 130 may have a thickness between 5 nm and 10 nm. In the present disclosure, a sum of the thicknesses of the hole transport layer 110, the co-evaporation layer 120 and the blue light-emitting auxiliary layer 130 may range from 95 nm to 130 nm, which approaches a thickness of a single hole transport layer in the related art. In the present disclosure, since the co-evaporation layer 120 also has a hole transport property, the performance of the blue organic light-emitting diode can be ensured without increasing the thickness of the hole transport layer 110, and the driving voltage for driving the blue organic light-emitting diode can also be reduced.

Further, In some embodiments, the co-evaporation layer 120 may have a thickness between 3 nm and 20 nm.

In the present disclosure, other layers of the blue organic light-emitting diode are not particularly limited. In some embodiments, as shown in FIG. 1, the blue organic light-emitting diode further includes an anode 160 disposed on a side of the hole transport layer 110 away from the co-evaporation layer 120, a hole block layer (HBL) 170 disposed between the electron transport layer 150 and the blue light-emitting layer 140, and a cathode 180 disposed on a side of the electron transport layer 150 away from the hole block layer 170.

Due to the presence of an electric field formed by the cathode 180 and the anode 160, electrons and holes may continue moving after moving into the blue light-emitting layer 140, for example, the holes may further move toward the cathode 180. The hole block layer 170 can form a hole mobility barrier due to its special energy level structure, and prevent the holes from moving further.

In some embodiments, the blue organic light-emitting diode may further include a hole injection layer (HIL) disposed between the anode and the hole transport layer.

In some embodiments, the blue organic light-emitting diode further includes an electron injection layer (EIL) disposed between the cathode and the electron transport layer.

As a second aspect of the present disclosure, there is provided a display device including a plurality of pixel units, each pixel unit includes a plurality of organic light-emitting diodes capable of emitting light different colors, the plurality of organic light-emitting diodes include a blue organic light-emitting diode that emits blue light, and the blue organic light-emitting diode is the above blue organic light-emitting diode according to the present disclosure.

As described above, since the co-evaporation layer 120 is made from a material including the material of the hole transport layer 110 and the material of the blue light-emitting auxiliary layer 130, the interface barrier between the co-evaporation layer 120 and the hole transport layer 110 is small, the interface barrier between the co-evaporation layer 120 and the blue light-emitting auxiliary layer 130 is also small, and thus holes can smoothly pass through the co-evaporation layer 120.

The transport speed of holes is greater than that of electrons. In a case where the blue organic light-emitting diode emits light under a low current, holes can be smoothly injected into the blue light-emitting layer 140 after being sequentially buffered by the co-evaporation layer 120 and the blue light-emitting auxiliary layer 130 between the hole transport layer 110 and the blue light-emitting layer 140 in an injection process, without being accumulated at the interface of the blue light-emitting auxiliary layer 130 and the blue light-emitting layer 140, so that the blue organic light-emitting diode can emit light normally, which in turn avoids a redness phenomenon under low gray scale display of the display device including the blue organic light-emitting diode, and improves the display effect of the display device.

As an optional implementation, each pixel unit includes organic light-emitting diodes of three colors, namely, a red organic light-emitting diode, a green organic light-emitting diode and a blue organic light-emitting diode.

In the present disclosure, the display device may be a rigid display device or a flexible display device. The organic light-emitting diode is particularly suitable for use in a flexible display device because of its solid-state luminescence characteristic.

### Embodiment

Manufacturing the blue organic light-emitting diode shown in FIG. 1 includes steps of:

forming a transparent ITO electrode as an anode 160;

forming a hole transport layer 110 having a thickness of 115 nm by taking NPB as an evaporation source, where the HOMO energy level of the formed hole transport layer is −5.37 eV;

forming a co-evaporation layer 120 having a thickness of 5 nm by taking a mixture of NPB and a dibenzofuran-triphenylamine derivative as an evaporation source, where in the evaporation source, a weight percent of the dibenzofuran-triphenylamine derivative is 95%, and a weight percent of NPB is 5%;

forming a blue light-emitting auxiliary layer 130 having a thickness of 10 nm by taking a dibenzofuran-triphenylamine derivative as an evaporation source, where the HOMO energy level of the blue light-emitting auxiliary layer 130 is −5.72 eV, and a difference between the HOMO energy level of the blue light-emitting auxiliary layer and the HOMO energy level of the hole transport layer is 0.35 eV;

forming a blue light-emitting layer 140 having a thickness of 30 nm by taking a mixture of tetramethyl phenyl-diarylamine pyrene doped with a 9,10-dinaphthylanthracene-like material as an evaporation source, where the doping ratio is 3%, and the HOMO energy level of the dopant is −5.96 eV;

forming a hole block layer 170 having a thickness of 10 nm by taking BCP as an evaporation source;

forming an electron transport layer 150 having a thickness of 30 nm by taking a triazine-pyrimidine derivative as an evaporation source; and

forming an Al layer having a thickness of 20 nm as a cathode 180, thereby finally obtaining a blue light-emitting diode.

### Comparative Example

Manufacturing a blue organic light-emitting diode includes steps of:

forming a transparent ITO electrode as an anode;

forming a hole transport layer having a thickness of 120 nm by taking NPB as an evaporation source, where the HOMO energy level of the formed hole transport layer is −5.37 eV;

forming a blue light-emitting auxiliary layer having a thickness of 10 nm by taking a dibenzofuran-triphenylamine derivative as an evaporation source, where the HOMO energy level is −5.53 eV;

forming a blue light-emitting layer 140 having a thickness of 30 nm by taking a mixture of tetramethyl phenyl-diarylamine pyrene doped with 9, 10 dinaphthyl anthracene materials as an evaporation source, where the doping ratio is 3%, and the HOMO energy level of the dopant is −5.96 eV;

forming a hole block layer having a thickness of 10 nm by taking BCP as an evaporation source;

forming an electron transport layer having a thickness of 30 nm by taking a triazine-pyrimidine derivative as an evaporation source; and

forming an Al layer having a thickness of 20 nm as a cathode, thereby finally obtaining a blue light-emitting diode.

### Test Example

An current-voltage-luminance (IVL) test is performed on the blue organic light-emitting diodes manufactured in the embodiment and the comparative example, and a result is obtained as shown in FIG. 2.

As can be seen from FIG. 2, in the case of a low current, the luminance of the blue organic light-emitting diode in the embodiment is higher than that of the organic light-emitting diode in the comparative example.

It could be understood that the above implementations are merely exempleryt implementations for illustrating the principle of the present disclosure, but the present disclosure is not limited thereto. Various variations and improvements can be made by a person of ordinary skill in the art without departing from the spirit and essence of the present disclosure. These variations and improvements are also considered to be within the protection scope of the present disclosure.

1. A blue organic light-emitting diode, comprising: a hole transport layer, a co-evaporation layer, a blue light-emitting auxiliary layer, a blue light-emitting layer and an electron transport layer which are sequentially stacked, wherein a material of the co-evaporation layer comprises a mixture of a material of the hole transport layer and a material of the blue light-emitting auxiliary layer.

2. The blue organic light-emitting diode of claim 1, wherein a weight percentage of the material of the blue light-emitting auxiliary layer in the co-evaporation layer is 50 wt % to 99.9 wt %.

3. The blue organic light-emitting diode of claim 1, wherein a difference between a HOMO energy level of the blue light-emitting auxiliary layer and a HOMO energy level of the blue light-emitting layer is not more than 0.3 eV.

4. The blue organic light-emitting diode of claim 3, wherein the HOMO energy level of the blue light-emitting auxiliary layer is between −6 eV and −5.5 eV.

5. The blue organic light-emitting diode of claim 4, wherein the HOMO energy level of the blue light-emitting auxiliary layer is between −6 eV and −5.6 eV.

6. The blue organic light-emitting diode of claim 1, wherein a thickness of the co-evaporation layer is between 1 nm and 50 nm.

7. The blue organic light-emitting diode of claim 6, wherein the thickness of the co-evaporation layer is between 3 nm and 20 nm.

8. The blue organic light-emitting diode of claim 1, further comprising an anode on a side of the hole transport layer away from the co-evaporation layer, a hole block layer between the blue light-emitting layer and the electron transport layer, a cathode on a side of the electron transport layer away from the hole block layer, a hole injection layer between the anode and the hole transport layer, and an electron injection layer between the cathode and the electron transport layer.

9. A display device, comprising a plurality of pixel units, each pixel unit comprising a plurality of organic light-emitting diodes capable of emitting light of different colors, the plurality of organic light-emitting diodes comprising a blue organic light-emitting diode emitting blue light, wherein the blue organic light-emitting diode is the blue organic light-emitting diode of claim 1.

10. A display device of claim 9, wherein the display device is a flexible display device.

11. The blue organic light-emitting diode of claim 2, wherein a thickness of the co-evaporation layer is between 1 nm and 50 nm.

12. The blue organic light-emitting diode of claim 3, wherein a thickness of the co-evaporation layer is between 1 nm and 50 nm.

13. The blue organic light-emitting diode of claim 4, wherein a thickness of the co-evaporation layer is between 1 nm and 50 nm.

14. The blue organic light-emitting diode of claim 5, wherein a thickness of the co-evaporation layer is between 1 nm and 50 nm.

15. The blue organic light-emitting diode of claim 11, wherein the thickness of the co-evaporation layer is between 3 nm and 20 nm.

16. The blue organic light-emitting diode of claim 12, wherein the thickness of the co-evaporation layer is between 3 nm and 20 nm.

17. The blue organic light-emitting diode of claim 13, wherein the thickness of the co-evaporation layer is between 3 nm and 20 nm.

18. The blue organic light-emitting diode of claim 14, wherein the thickness of the co-evaporation layer is between 3 nm and 20 nm.

19. The blue organic light-emitting diode of claim 5, further comprising an anode on a side of the hole transport layer away from the co-evaporation layer, a hole block layer between the blue light-emitting layer and the electron transport layer, a cathode on a side of the electron transport layer away from the hole block layer, a hole injection layer between the anode and the hole transport layer, and an electron injection layer between the cathode and the electron transport layer.

20. The blue organic light-emitting diode of claim 18, further comprising an anode on a side of the hole transport layer away from the co-evaporation layer, a hole block layer between the blue light-emitting layer and the electron transport layer, a cathode on a side of the electron transport layer away from the hole block layer, a hole injection layer between the anode and the hole transport layer, and an electron injection layer between the cathode and the electron transport layer.
